(19) United States
(12) Patent Application Publication
(10) Pub. No.: US 2017/0053825 A1
(43) Pub. Date: Feb. 23, 2017

(54) SEMICONDUCTOR DEVICES HAVING FIN FIELD EFFECT TRANSISTORS WITH A SINGLE LINER PATTERN IN A FIRST REGION AND A DUAL LINER PATTERN IN A SECOND REGION AND METHODS FOR MANUFACTURING THE SAME

(71) Applicants: KANG-ILL SEO, CHUNGCHEONGBUK-DO (KR); BOMSOO KIM, SEOUL (KR); JI-HOON CHA, SEOUL (KR)

(72) Inventors: KANG-ILL SEO, CHUNGCHEONGBUK-DO (KR); BOMSOO KIM, SEOUL (KR); JI-HOON CHA, SEOUL (KR)

(21) Appl. No.: 14/831,087

(22) Filed: Aug. 20, 2015

(51) Int. Cl. H01L 21/762; H01L 21/311

(52) U.S. Cl. CPC H01L 21/76224; H01L 21/31144

(57) ABSTRACT

A method for manufacturing a semiconductor device includes forming a first active pattern in a first region of a substrate and a second active pattern in a second region of the substrate, wherein the first and second active patterns project from the substrate, forming a second liner pattern on the substrate and the second active pattern in the second region, wherein the second liner pattern has a second polarity, forming a first liner pattern on the substrate and the first active pattern in the first region, wherein the first liner pattern has a first polarity different from the second polarity, forming an isolation pattern on the first liner pattern in the first region and the second liner pattern in the second region, and exposing the first active pattern and the second active pattern by recessing the isolation pattern.

### TECHNICAL FIELD

The present inventive concept relates to semiconductor devices having fin field effect transistors and methods for manufacturing the same.

### DESCRIPTION OF THE RELATED ART

A fin field effect transistor (finFET), which is a three-dimensional (3D) transistor, has a short distance between a source and a drain, but is vulnerable to punch-through leakage. A finFET experiencing leakage due to punch-through becomes unusable. To prevent this, ion injection for doping a dopant having a conduction type that is opposite to the conduction type of the finFET may be performed. However, excessive ion injection may negatively influence other characteristics of the finFET.

### SUMMARY

In an example embodiment of the present inventive concept, there is provided a method for manufacturing a semiconductor device comprising forming a first active pattern in a first region of a substrate and a second active pattern in a second region of the substrate, wherein the first and second active patterns project from the substrate, forming a second liner pattern on the substrate and the second active pattern in the second region, wherein the second liner pattern has a second polarity, forming a first liner pattern on the substrate and the first active pattern in the first region, wherein the first liner pattern has a first polarity different from the second polarity, forming an isolation pattern on the first liner pattern in the first region and the second liner pattern in the second region, and exposing the first active pattern and the second active pattern by recessing the isolation pattern.

In an example embodiment of the present inventive concept, the second polarity is a positive polarity.

In an example embodiment of the present inventive concept, the second liner pattern includes nitride.

In an example embodiment of the present inventive concept, the second liner pattern includes SiN.

In an example embodiment of the present inventive concept, the first polarity is a negative polarity.

In an example embodiment of the present inventive concept, the first liner pattern includes oxide.

In an example embodiment of the present inventive concept, the first region includes an N-type metal oxide semiconductor (NMOS) region, and the second region includes a P-type metal oxide semiconductor (PMOS) region.

In an example embodiment of the present inventive concept, the forming of the second liner pattern on the substrate and the second active pattern in the second region comprises: forming the second liner pattern on the substrate in the first and second regions, on the first active pattern in the first region, and on the second active pattern in the second region; and removing the second liner pattern from the first region.

In an example embodiment of the present inventive concept, the removing of the second liner pattern from the first region comprises: forming a mask pattern in the second region; and etching the second liner pattern in the first region using the mask pattern.

In an example embodiment of the present inventive concept, the etching is a dry etching or a wet etching.

In an example embodiment of the present inventive concept, the method further comprises forming the first liner pattern on the second liner pattern in the second region.

In an example embodiment of the present inventive concept, parts of side surfaces of the first active pattern and the second active pattern are exposed by recessing the isolation pattern.

In an example embodiment of the present inventive concept, the first active pattern and the second active pattern are exposed by removing parts of the first liner pattern formed in the first region and parts of the first liner pattern formed in the second region while recessing the isolation pattern.

In an example embodiment of the present inventive concept, an exposed region of the second active pattern has the second polarity.

In an example embodiment of the present inventive concept, the first active pattern and the second active pattern are exposed by removing a part of the second liner pattern formed in the second region after removing the part of the first liner pattern formed in the first region and the part of the first liner pattern formed in the second region while recessing the isolation pattern.

In an example embodiment of the present inventive concept, an exposed region of the first active pattern has the first polarity.

In an example embodiment of the present inventive concept, a method for manufacturing a semiconductor device comprises forming a first active pattern in a first region of a substrate and a second active pattern in a second region of the substrate, wherein the first and second active patterns project from the substrate; forming a second liner pattern and a first liner pattern on the substrate and the second active pattern in the second region, wherein the second liner pattern has a second polarity and the first liner pattern has a first polarity different from the second polarity; forming a third liner pattern on the substrate and the first active pattern in the first region, wherein the third liner pattern has the first polarity; forming an isolation pattern on the third liner pattern in the first region and the second liner pattern in the second region, and exposing the first active pattern and the second active pattern by recessing the isolation pattern.

In an example embodiment of the present inventive concept, the forming of the second liner pattern and the first liner pattern on the substrate and the second active pattern in the second region comprises: forming the second liner pattern on the substrate and the first active pattern in the first region, and on the substrate and the second active pattern in the second region; forming the first liner pattern on the second liner pattern in the first region and the second region; and removing the first liner pattern and the second liner pattern from the first region.

In an example embodiment of the present inventive concept, the removing of the first liner pattern and the second liner pattern from the first region comprises: forming a mask pattern in the second region; first etching the first liner pattern in the first region using the mask pattern; and second etching the second liner pattern in the first region using the mask pattern.

In an example embodiment of the present inventive concept, the forming of the third liner pattern on the substrate and the first active pattern in the first region further comprises forming the third liner pattern on the first liner pattern in the second region.

In an example embodiment of the present inventive concept, the exposing of the first active pattern and the second active pattern by recessing the isolation pattern comprises removing a part of the third liner pattern formed in the first region and a part of the third liner pattern formed in the second region and a part of the first liner pattern formed in the second region while recessing the isolation pattern.

In an example embodiment of the present inventive concept, the exposing of the first active pattern and the second active pattern by recessing the isolation pattern further comprises removing a part of the second liner pattern formed in the second region after removing the part of the third liner pattern formed in the first region, the part of the third liner pattern formed in the second region and the part of the first liner pattern formed in the second region while recessing the isolation pattern.

In an example embodiment of the present inventive concept, the second polarity is a positive polarity, and the first polarity is a negative polarity.

In an example embodiment of the present inventive concept, the second liner pattern includes nitride, and the first liner pattern and the third liner pattern include oxide.

In an example embodiment of the present inventive concept, a semiconductor device comprises a substrate including a first region and a second region, a first active pattern projecting from the substrate in the first region, a second active pattern projecting from the substrate in the second region, a first liner pattern formed along an upper surface of the substrate and a part of a side surface of the first active pattern in the first region, and a second liner pattern formed along an upper surface of the substrate and a part of a side surface of the second active pattern in the second region, wherein the second liner pattern has a polarity that is different from a polarity of the first liner pattern.

In an example embodiment of the present inventive concept, the first liner pattern has a negative polarity, and the second liner pattern has a positive polarity.

In an example embodiment of the present inventive concept, the first liner pattern includes oxide, and the second liner pattern includes nitride.

In an example embodiment of the present inventive concept, the first liner pattern includes Al₂O₃, HfO₂, or TaO.

In an example embodiment of the present inventive concept, the second liner pattern includes SiN.

In an example embodiment of the present inventive concept, the first active pattern includes a lower region having a side surface on which the first liner pattern is formed, and an upper region having a side surface on which the first liner pattern is not formed, and the second active pattern includes a lower region having a side surface on which the second liner pattern is formed, and an upper region having a side surface on which the second liner pattern is not formed.

In an example embodiment of the present inventive concept, the upper region of the first active pattern has a polarity that is different from the polarity of the second liner pattern.

In an example embodiment of the present inventive concept, the upper region of the second active pattern has a polarity that is different from the polarity of the first liner pattern.

In an example embodiment of the present inventive concept, the upper region of the first active pattern has a polarity that is different from a polarity of the upper region of the second active pattern.

In an example embodiment of the present inventive concept, the first region includes an NMOS region, and the second region includes a PMOS region.

In an example embodiment of the present inventive concept, the semiconductor device comprises an isolation pattern formed on the first liner pattern and the second liner pattern.

In an example embodiment of the present inventive concept, a method for manufacturing a semiconductor device comprises: forming a first active pattern in a first area of a substrate, the first active pattern protruding from the substrate; forming a second active pattern in a second area of the substrate, the second active pattern protruding from the substrate; forming a first liner pattern in the first area; forming a second liner pattern in the second area; exposing a first portion of the first active pattern by removing part of the first liner pattern; and exposing a first portion of the second active pattern by removing part of the second liner pattern, wherein the first portion of the first active pattern has a first polarity and the first portion of the second active pattern has a second polarity.

In an example embodiment of the present inventive concept, the first liner pattern is disposed on a second portion of the first active pattern and the second liner pattern is disposed on a second portion of the second active pattern.

In an example embodiment of the present inventive concept, the second portion of the first active pattern has the second polarity and the second portion of the second active pattern has the first polarity.

In an example embodiment of the present inventive concept, the first liner pattern has the first polarity and the second liner pattern has the second polarity.

### BRIEF DESCRIPTION OF THE DRAWINGS

The above and other features of the present inventive concept will become more apparent by describing in detail example embodiments thereof in conjunction with the accompanying drawings, in which:

FIG. 1 is a perspective view of a semiconductor device according to an example embodiment of the present inventive concept;

FIG. 2 is a cross-sectional view of the semiconductor device of FIG. 1 taken along lines A-A and B-B, according to an example embodiment of the present inventive concept;

FIG. 3 is a perspective view of a semiconductor device according to an example embodiment of the present inventive concept;

FIG. 4 is a cross-sectional view of the semiconductor device of FIG. 3 taken along lines A-A and B-B, according to an example embodiment of the present inventive concept;

FIG. 5 is a perspective view of a semiconductor device according to an example embodiment of the present inventive concept;

FIG. 6 is a cross-sectional view of the semiconductor device of FIG. 5 taken along lines A-A and B-B, according to an example embodiment of the present inventive concept;

FIGS. 7, 8, 9, 10, 11, 12, 13 and 14 are views of steps of a method for manufacturing a semiconductor device according to an example embodiment of the present inventive concept;

FIGS. 15, 16, 17, 18, 19, 20, 21 and 22 are views of steps of a method for manufacturing a semiconductor device according to an example embodiment of the present inventive concept;

FIG. 23 is a view of a semiconductor device according to example embodiments of the present inventive concept;

FIGS. 24 and 25 are diagrams of a semiconductor device that is manufactured by a method for manufacturing a semiconductor device according to an example embodiment of the present inventive concept;

FIG. 26 is a block diagram of a system on chip (SoC) system that includes a semiconductor device according to example embodiments of the present inventive concept;

FIG. 27 is a block diagram of an electronic system that includes a semiconductor device according to example embodiments of the present inventive concept; and

FIGS. 28, 29 and 30 are views of semiconductor systems to which a semiconductor device according to example embodiments of the present inventive concept can be applied.

### DETAILED DESCRIPTION OF THE EMBODIMENTS

Example embodiments of the present inventive concept will be described in detail with reference to the accompanying drawings. The present inventive concept, however, may be embodied in various different forms, and should not be construed as being limited only to the illustrated embodiments. Unless otherwise noted, like reference numerals denote like elements throughout the attached drawings and written description, and thus descriptions may not be repeated. In the drawings, the sizes and relative sizes of layers and regions may be exaggerated for clarity.

As used herein, the singular forms “a”, “an” and “the” are intended to include the plural forms as well, unless the context clearly indicates otherwise.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present.

Hereinafter, a semiconductor device and a method for manufacturing the same according to example embodiments of the present inventive concept will be described with reference to the accompanying drawings.

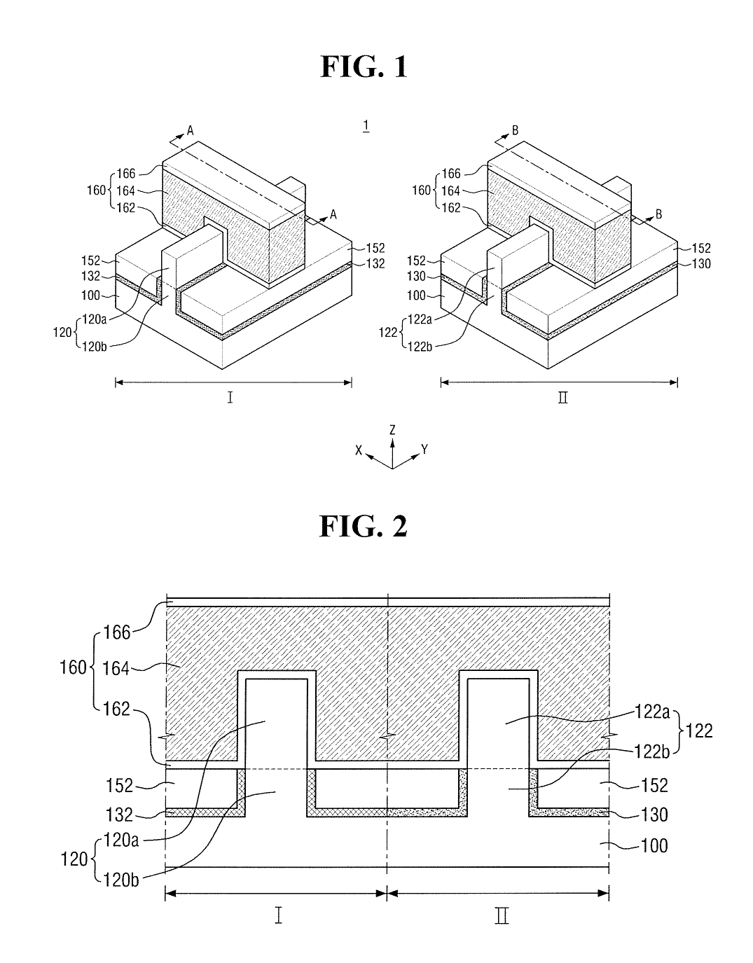

FIG. 1 is a perspective view of a semiconductor device according to an example embodiment of the present inventive concept, and FIG. 2 is a cross-sectional view of the semiconductor device of FIG. 1 taken along lines A-A and B-B, according to an example embodiment of the present inventive concept.

Referring to FIGS. 1 and 2, a semiconductor device 1 according to an example embodiment of the present inventive concept includes a substrate 100, a first active pattern 120, a second active pattern 122, a first liner pattern 132, a second liner pattern 130, and an isolation pattern 152. The semiconductor device 1 may be referred to hereafter as a memory device.

The substrate 100 may include a first region I and a second region II. The first region I and the second region II may include different types of dopants. In example embodiments of the present inventive concept, the first region I may include an N-type metal oxide semiconductor (NMOS) region, and the second region II may include a P-type metal oxide semiconductor (PMOS) region.

In example embodiments of the present inventive concept, the substrate 100 may include bulk silicon or Silicon-On-Insulator (SOI). For example, the substrate 100 may include a semiconductor material including Si, Ge, SiGe, GaP, GaAs, SiC, SiGeC, InAs, or InP. In a memory device according to an example embodiment of the present inventive concept, the substrate 100 and the first and second active patterns 120 and 122 include silicon, but the present inventive concept is not limited thereto.

The first active pattern 120 is formed to project from the substrate 100 in the first region I. In other words, the first active pattern 120 may protrude outward or upward from the substrate 100. For example, the first active pattern 120 may be formed to project from the first region I in a first direction Z and to extend in a second direction Y that crosses the first direction Z. On the other hand, the second active pattern 122 may be formed to project from the substrate 100 in the second region II. In other words, the second active pattern 220 may protrude outward or upward from the substrate 100. For example, the second active pattern 122 may be formed to project from the second region II in the first direction Z and to extend in the second direction Y that crosses the first direction Z. In other words, in the memory device according to an example embodiment of the present inventive concept, the first active pattern 120 and the second active pattern 122 may be fin type active patterns or active fins.

FIG. 1 illustrates that the first active pattern 120 and the second active pattern 122 are formed to extend in the same direction, in other words, in the second direction Y, but the present inventive concept is not limited thereto. For example, the first active pattern 120 may be formed to extend in the second direction Y, and the second active pattern 122 may be formed to extend in a third direction X that crosses the second direction Y. In example embodiments of the present inventive concept, the first active pattern 120 and the second active pattern 122 may be a part of the substrate 100, or may be included in an epitaxial layer that is grown from the substrate 100.

The first liner pattern 132 is formed along an upper surface of the substrate 100 and a part of a side surface of the first active pattern 120 in the first region I. On the other hand, the second liner pattern 130 is formed along an upper surface of the substrate 100 and a part of a side surface of the second active pattern 122 in the second region II. For example, the first active pattern 120 may include an upper region 120a and a lower region 120b. The first liner pattern 132 may be formed on a side surface of the lower region 120b of the first active pattern 120, and the first liner pattern 132 may not be formed on a side surface of the upper region 120a of the first active pattern 120. The second active pattern 122 may include an upper region 122a and a lower region 122b. Further, the second liner pattern 130 may be formed on a side surface of the lower region 122b of the second active pattern 122, and the second liner pattern 130 may not be formed on a side surface of the upper region 122a of the second active pattern 122.

The first liner pattern 132 and the second liner pattern 130 may have different polarities. For example, the first liner pattern 132 may have a negative polarity, and the second liner pattern 130 may have a positive polarity. On the other hand, the first liner pattern 132 may include oxide, and the second liner pattern 130 may include nitride. In example embodiments of the present inventive concept, the first liner pattern 132 may include Al₂O₃, HfO₂, or TaO. These materials can be negatively charged. Further, in example embodiments of the present inventive concept, the second liner pattern 130 may include SiN. This material can be positively charged. Since the first liner pattern 132 and the second liner pattern 130 include materials having different polarities, they have different polarities.

In this embodiment, the polarity of the upper region 120a of the first active pattern 120 may be different from the polarity of the second liner pattern 130. The polarity of the upper region 122a of the second active pattern 122 may be different from the polarity of the first liner pattern 132. On the other hand, the polarity of the upper region 120a of the first active pattern 120 may be different from the polarity of the upper region 122a of the second active pattern 122.

For example, in the case where the first region I is an NMOS region and the second region II is a PMOS region, the polarity of the upper region 120a of the first active pattern 120 may be a negative polarity, and the polarity of the second liner pattern 130 may be a positive polarity. Further, the polarity of the upper region 122a of the second active pattern 122 may be a positive polarity, and the polarity of the first liner pattern 132 may be a negative polarity. In this case, the polarity of the lower region 120b of the first active pattern 120 may be a positive polarity, and the polarity of the lower region 122b of the second active pattern 122 may be a negative polarity. With the above-described structure of the semiconductor device 1 according to an example embodiment of the present inventive concept, charge mobility can be increased by suppressing a punch-through phenomenon so that ion injection is not needed or is kept to a minimum. Further, by forming the fin with a narrow width in the semiconductor device 1 according to an example embodiment of the present inventive concept, high density and high performance devices can be realized.

The isolation pattern 152 is formed on the first liner pattern 132 and the second liner pattern 130. In example embodiments of the present inventive concept, the isolation pattern 152 may be a Shallow Trench Isolation (STI) liner. In example embodiments of the present inventive concept, the isolation pattern 152 may be formed on the first liner pattern 132 and the second liner pattern 130 using a Chemical Vapor Deposition (CVD) process, an Atomic Layer Deposition (ALD) process, and the like.

In addition, the semiconductor device 1 according to an example embodiment of the present inventive concept may further include a dummy gate structure 160. The dummy gate structure 160 includes a dummy gate insulating layer 162 and a dummy gate electrode 164 that extend in the third direction X. In example embodiments of the present inventive concept, the dummy gate insulating layer 162 may be a silicon oxide layer, and the dummy gate electrode 164 may include polysilicon. In example embodiments of the present inventive concept, the dummy gate structure 160 may be formed through an etching process using a mask pattern 166. The dummy gate structure 160 may be replaced by a gate structure that includes a gate insulating layer and a gate electrode.

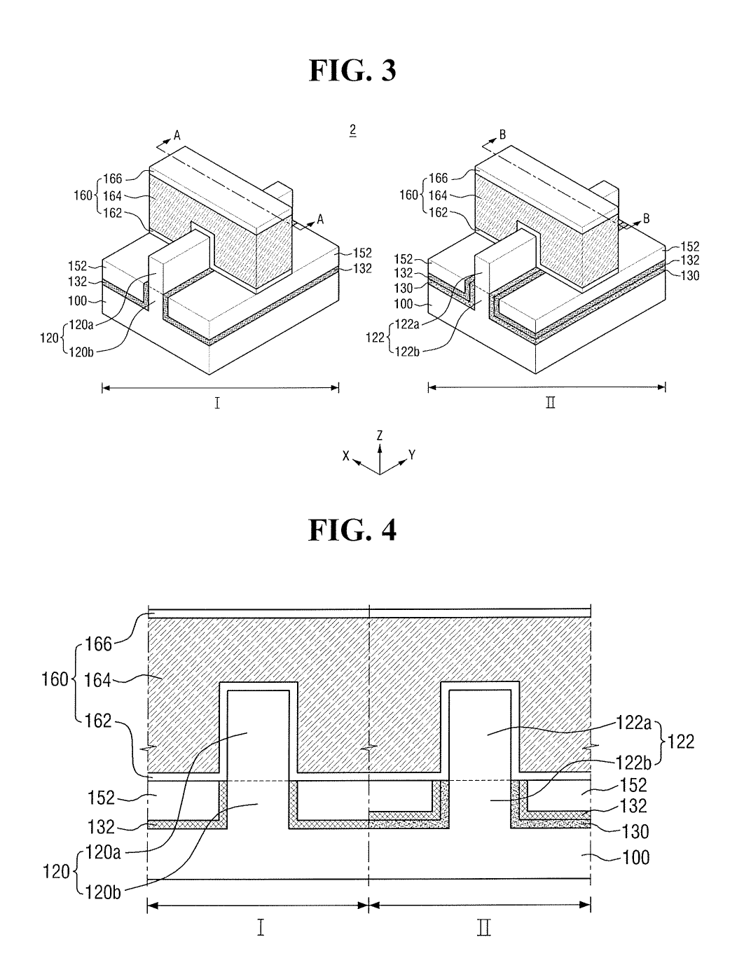

FIG. 3 is a perspective view of a semiconductor device according to an example embodiment of the present inventive concept, and FIG. 4 is a cross-sectional view of the semiconductor device of FIG. 3 taken along lines A-A and B-B, according to an example embodiment of the present inventive concept.

Referring to FIGS. 3 and 4, a semiconductor device 2 according to an example embodiment of the present inventive concept includes a substrate 100, a first active pattern 120, a second active pattern 122, a first liner pattern 132, a second liner pattern 130, and an isolation pattern 152.

The semiconductor device 2 is different from the semiconductor device 1 in that the first liner pattern 132 is formed on the second liner pattern 132 in the second region II.

In other words, in the first region I, the first liner pattern 132 may be formed on a side surface of a lower region 120b of the first active pattern 120, and the first liner pattern 132 may not be formed on a side surface of an upper region 120a of the first active pattern 120. On the other hand, in the second region II, the second liner pattern 130 and the first liner pattern 132 may be formed on a side surface of a lower region 122b of the second active pattern 122, and the second liner pattern 130 and the first liner pattern 132 may not be formed on a side surface of an upper region 122a of the second active pattern 122.

In this embodiment, the polarity of the upper region 120a of the first active pattern 120 may be different from the polarity of the second liner pattern 130. The polarity of the upper region 122a of the second active pattern 122 may be different from the polarity of the first liner pattern 132, and may be equal to the polarity of the second liner pattern 132. On the other hand, the polarity of the upper region 120a of the first active pattern 120 may be different from the polarity of the upper region 122a of the second active pattern 122.

For example, in the case where the first region I is an NMOS region and the second region II is a PMOS region, the polarity of the upper region 120a of the first active pattern 120 may be a negative polarity, and the polarity of the second liner pattern 130 may be a positive polarity. Further, the polarity of the upper region 122a of the second active pattern 122 may be a positive polarity, and the polarity of the first liner pattern 132 may be a negative polarity. In this case, the polarity of the lower region 120b of the first active pattern 120 may be a positive polarity, and the polarity of the lower region 122b of the second active pattern 122 may be a negative polarity.

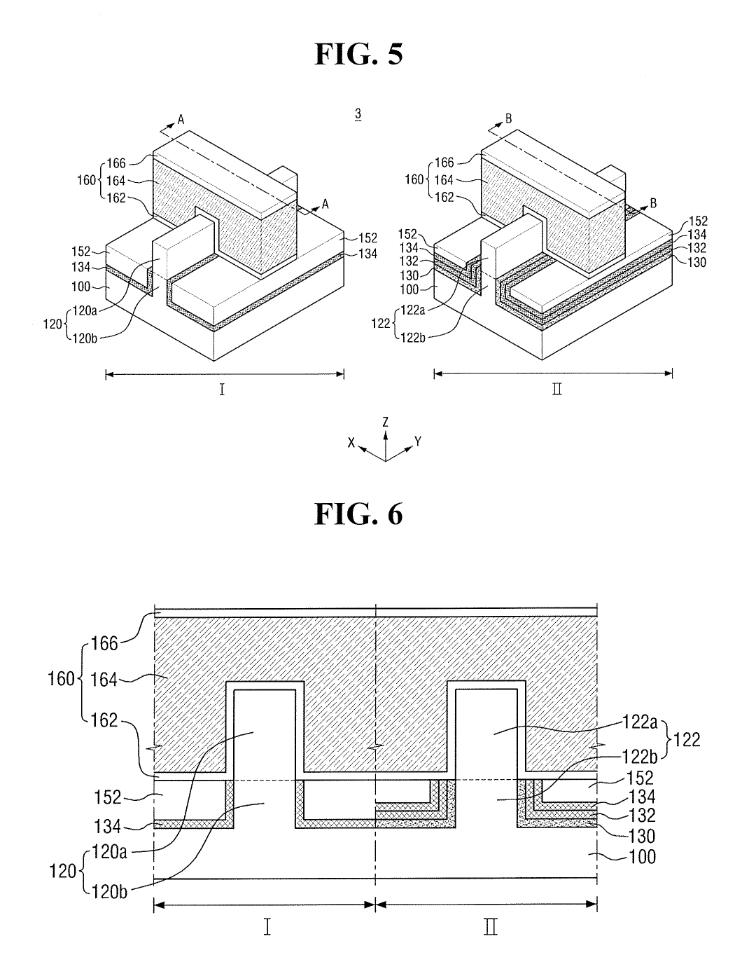

FIG. 5 is a perspective view of a semiconductor device according to an example embodiment of the present inventive concept, and FIG. 6 is a cross-sectional view of the semiconductor device of FIG. 5 taken along lines A-A and B-B, according to an example embodiment of the present inventive concept.

Referring to FIGS. 5 and 6, a semiconductor device 3 according to an example embodiment of the present inventive concept includes a substrate 100, a first active pattern 120, a second active pattern 122, a first liner pattern 132, a second liner pattern 130, a third liner pattern 134, and an isolation pattern 152.

The semiconductor device 3 is different from the semiconductor devices 1 and 2 in that the third liner pattern 134 is formed along an upper surface of the substrate 100 and a part of a side surface of the second active pattern 122 in the first region I. Further, the semiconductor device 3 is different from the semiconductor devices 1 and 2 in that the second liner pattern 130 is formed along an upper surface of the substrate 100 and a part of a side surface of the second active pattern 122 in the second region II, the first liner pattern 132 is formed on the second liner pattern 130 in the second region II, and the third liner pattern 134 is formed on the first liner pattern 132 in the second region II.

In other words, in the first region I, the third liner pattern 134 may be formed on a side surface of a lower region 120b of the first active pattern 120, and the third liner pattern 134 may not be formed on a side surface of an upper region 120a of the first active pattern 120. On the other hand, in the second region II, the second liner pattern 130, the first liner pattern 132, and the third liner pattern 134 may be formed on a side surface of a lower region 122b of the second active pattern 122, and the second liner pattern 130, the first liner pattern 132, and the third liner pattern 134 may not be formed on a side surface of an upper region 122a of the second active pattern 122.

In this embodiment, the polarity of the upper region 120a of the first active pattern 120 may be different from the polarity of the second liner pattern 130. The polarity of the upper region 122a of the second active pattern 122 may be different from the polarity of the first liner pattern 132 and the third liner pattern 134, and may be equal to the polarity of the second liner pattern 132. On the other hand, the polarity of the upper region 120a of the first active pattern 120 may be different from the polarity of the upper region 122a of the second active pattern 122.

For example, in the case where the first region I is an NMOS region and the second region II is a PMOS region, the polarity of the upper region 120a of the first active pattern 120 may be a negative polarity, and the polarity of the second liner pattern 130 may be a positive polarity. Further, the polarity of the upper region 122a of the second active pattern 122 may be a positive polarity, and the polarity of the first liner pattern 132 and the third liner pattern 134 may be a negative polarity. In this case, the polarity of the lower region 120b of the first active pattern 120 may be a positive polarity, and the polarity of the lower region 122b of the second active pattern 122 may be a negative polarity.

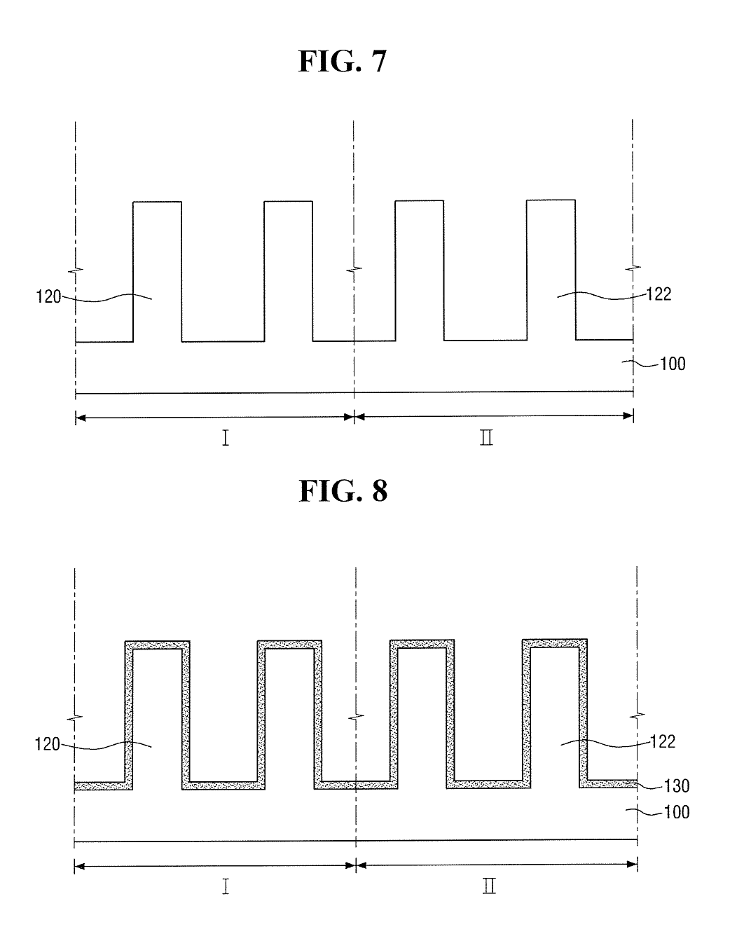

FIGS. 7 to 14 are views of steps of a method for manufacturing a semiconductor device according to an example embodiment of the present inventive concept.

Referring to FIG. 7, a first active pattern 120 that projects from a substrate 100 is formed in a first region I of the substrate 100, and a second active pattern 122 that projects from the substrate 100 is formed in a second region II of the substrate 100. In example embodiments of the present inventive concept, the first region I may include an NMOS region, and the second region II may include a PMOS transistor.

Referring to FIG. 8, a second liner pattern 130 is formed on the substrate 100, the first active pattern 120, and the second active pattern 122 in the first region I and the second region II. In example embodiments of the present inventive concept, the second liner pattern 130 may have a positive polarity. On the other hand, in example embodiments of the present inventive concept, the second liner pattern 130 may include nitride, for example, SiN.

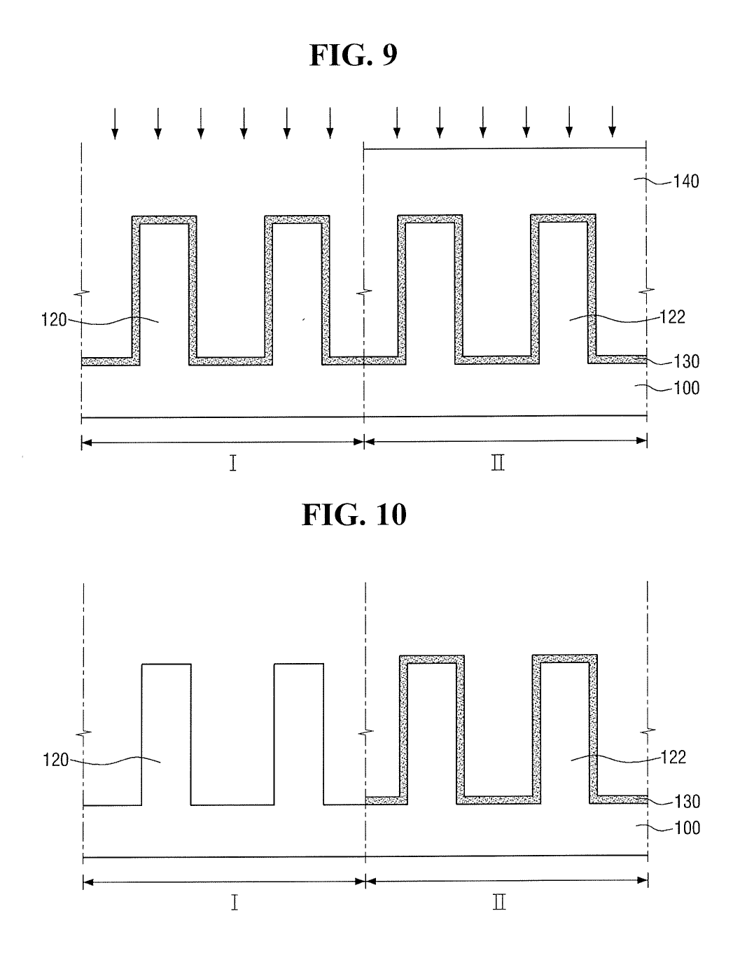

Referring to FIGS. 9 and 10, the second liner pattern 130 is removed from the first region I. In example embodiments of the present inventive concept, the step of removing the second liner pattern 130 from the first region I may include forming a mask pattern 140 in the second region II, and etching the second liner pattern 130 in the first region I using the mask pattern 140. The mask pattern 140 may be removed after the second liner pattern 130 in the first region I is etched using the mask pattern 140.

In example embodiments of the present inventive concept, the second liner pattern 130 of the first region I may be removed using a dry etching. The dry etching may be performed using a reactive ion etching (RIE) process. As an example of the dry etching, the second liner pattern 130 in the first region I may be removed using a mixed gas that includes oxygen as an etching gas. The mixed gas that is used as the etching gas may include chlorine in addition to oxygen. Further, the mixed gas may also include helium. As another example of the dry etching, the second liner pattern 130 in the first region I may be removed using a mixed gas that includes nitrogen and hydrogen. Further, in example embodiments of the present inventive concept, the second liner pattern 130 in the first region I may be removed using a wet etching.

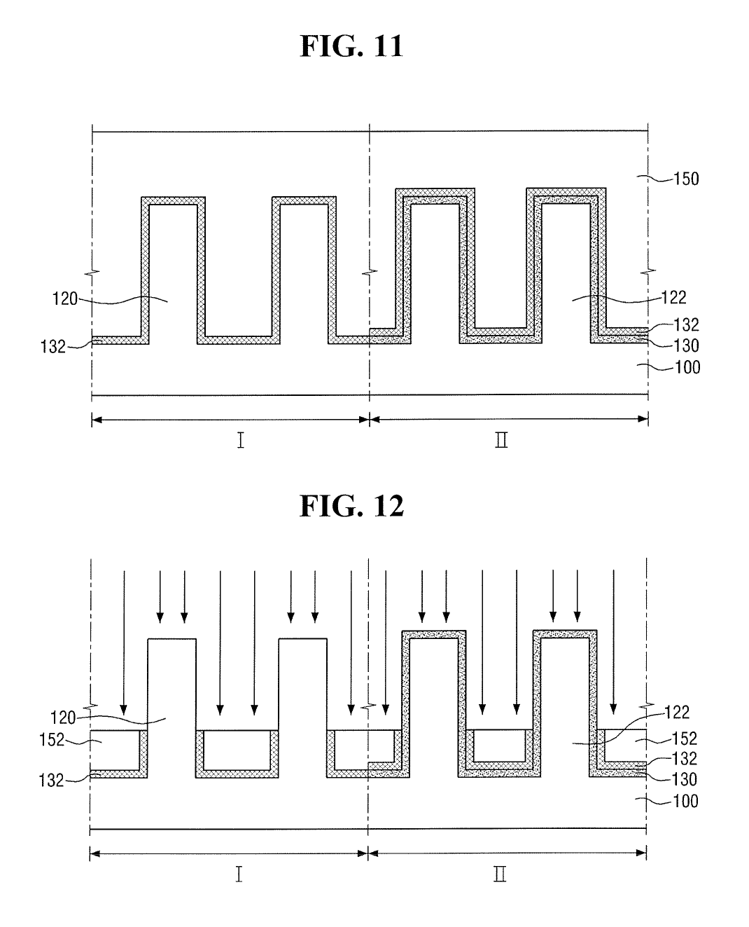

Referring to FIG. 11, a first liner pattern 132 is formed on the substrate 100 and the first active pattern 120 in the first region I and the second liner pattern 130 in the second region II. In example embodiments of the present inventive concept, the first liner pattern 132 may have a negative polarity. On the other hand, in example embodiments of the present inventive concept, the first liner pattern 132 may include Al₂O₃, HfO₂, or TaO.

As a result, the first liner pattern 132 is formed in the first region I, and the first liner pattern 132 and the second liner pattern 130 are formed in the second region II. Thereafter, an isolation pattern 150 is formed on the first liner pattern 132 and the second liner pattern 130 in the first region I and the second region II.

Referring to FIG. 12, the first active pattern 120 is exposed by recessing the isolation pattern 150 to form isolation pattern 152. The step of exposing the first active pattern 120 by recessing the isolation pattern 150 may include removing the first liner pattern 132 that is formed in the first region I by recessing the isolation pattern 150, and exposing parts of an upper surface and a side surface of the first active pattern 120.

On the other hand, in this embodiment, the first liner pattern 132 that is formed in the second region II may be removed when the first liner pattern 132 that is formed in the first region I is removed by recessing the isolation pattern 150. FIG. 12 illustrates that a part of the first liner pattern 132 remains in the second region II after the isolation pattern 150 is recessed. However, in example embodiments of the present inventive concept, the first liner pattern 132 in the second region II may be entirely removed after the isolation pattern 150 is recessed.

In the above-described manner, the first liner pattern 132 may be formed along the upper surface of the substrate 100 and the part of the side surface of the first active pattern 120 in the first region I.

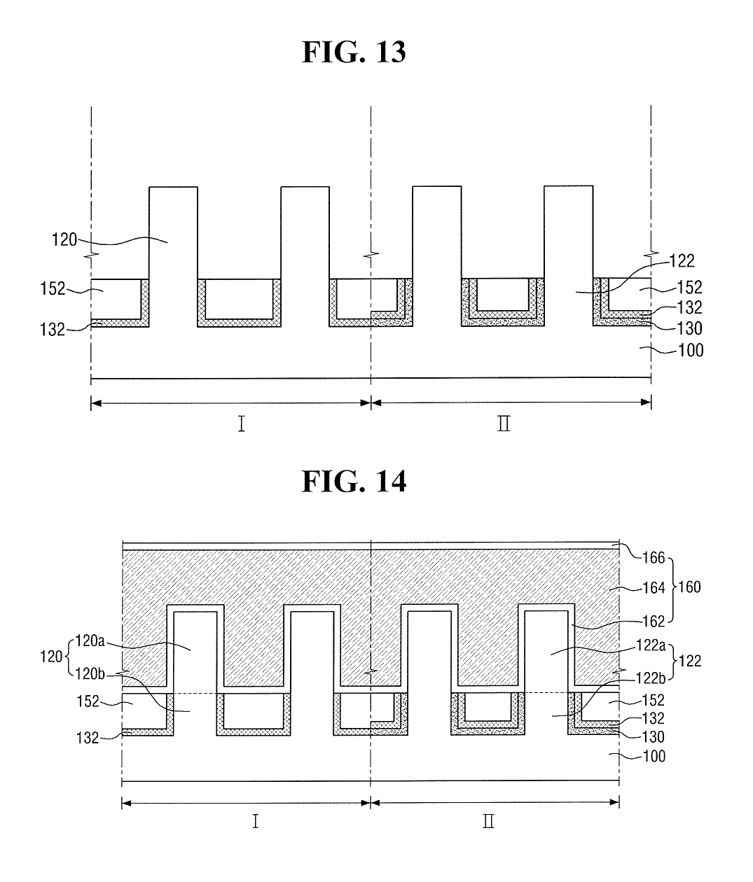

Referring to FIG. 13, after parts of the first liner pattern 132 formed in the first region I and the first liner pattern 132 formed in the second region II are removed through recessing the isolation pattern 150, a part of the second liner pattern 130 that is formed in the second region II is removed. For example, a part of the second liner pattern 130 covering a protruding part of the second active pattern 122 is removed. Accordingly, parts of the upper surface and the side surface of the second active pattern 122 are exposed.

In the above-described manner, the second liner pattern 130 may be formed along the upper surface of the substrate 100 and the part of the side surface of the second active pattern 122 in the second region II.

Referring to FIG. 14, a dummy gate structure 160 that includes a dummy gate insulating layer 162 and a dummy gate electrode 164 may be formed on the exposed first and second active patterns 120 and 122. In a subsequent process, the dummy gate structure 160 may be replaced by a gate structure that includes a gate insulating layer and a gate electrode. A mask pattern 166 may be used to form the dummy gate structure 160.

In this embodiment, the first liner pattern 132 may be formed on a side surface of the lower region 120b of the first active pattern 120 in the first region I, and the first liner pattern 132 may not be formed on a side surface of the upper region 120a of the first active pattern 120 in the first region I. Further, the second liner pattern 130 and the first liner pattern 132 may be formed on a side surface of the lower region 122b of the second active pattern 122 in the second region II, and the second liner pattern 130 and the first liner pattern 132 may not be formed on a side surface of the upper region 122a of the second active pattern 122 in the second region II.

On the other hand, in example embodiments of the present inventive concept, if the first liner pattern 132 in the second region II is entirely removed after the isolation pattern 150 is recessed, the second liner pattern 130 may be formed on the side surface of the lower region 122b of the second active pattern 122, and the second liner pattern 130 may not be formed on the side surface of the upper region 122a of the second active pattern 122.

In this embodiment, the polarity of the upper region 120a of the first active pattern 120 may be different from the polarity of the second liner pattern 130. The polarity of the upper region 122a of the second active pattern 122 may be different from the polarity of the first liner pattern 132, and may be equal to the polarity of the second liner pattern 132. On the other hand, the polarity of the upper region 120a of the first active pattern 120 may be different from the polarity of the upper region 122a of the second active pattern 122.

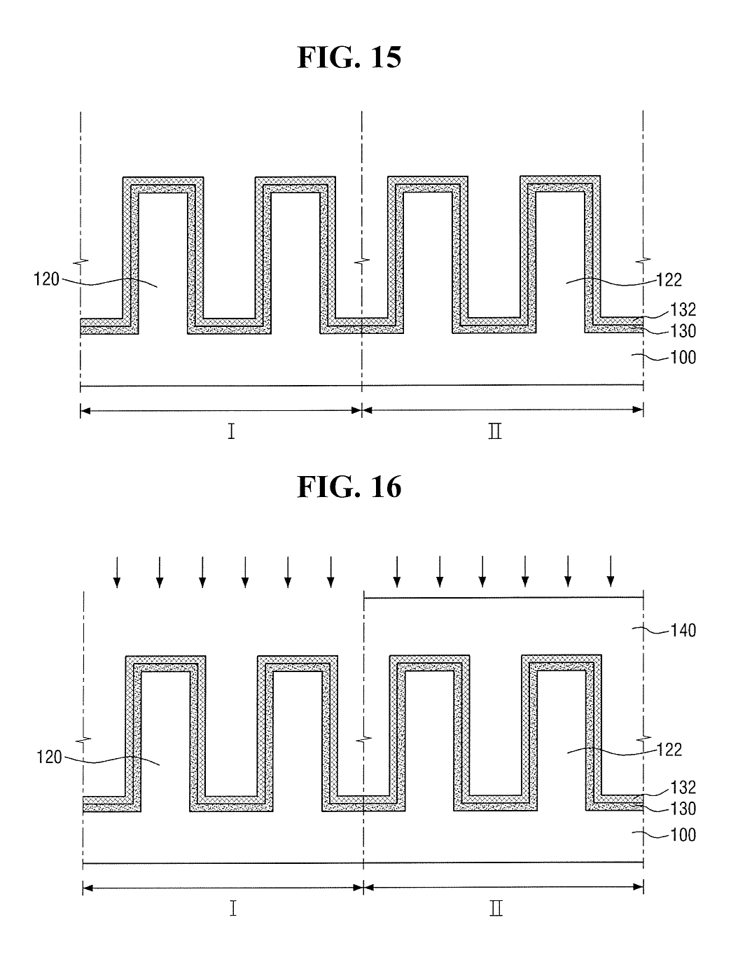

FIGS. 15 to 22 are views of steps of a method for manufacturing a semiconductor device according to an example embodiment of the present inventive concept.

Referring to FIG. 15, a second liner pattern 130 and a first liner pattern 132 are formed on a substrate 100, a first active pattern 120, and a second active pattern 122 in a first region I and a second region II. In example embodiments of the present inventive concept, the second liner pattern 130 may have a positive polarity. On the other hand, in example embodiments of the present inventive concept, the second liner pattern 130 may include nitride, for example, SiN. Further, in example embodiments of the present inventive concept, the first liner pattern 132 may have a negative polarity. On the other hand, in example embodiments of the present inventive concept, the first liner pattern 132 may include oxide, for example, Al₂O₃, HfO₂, or TaO.

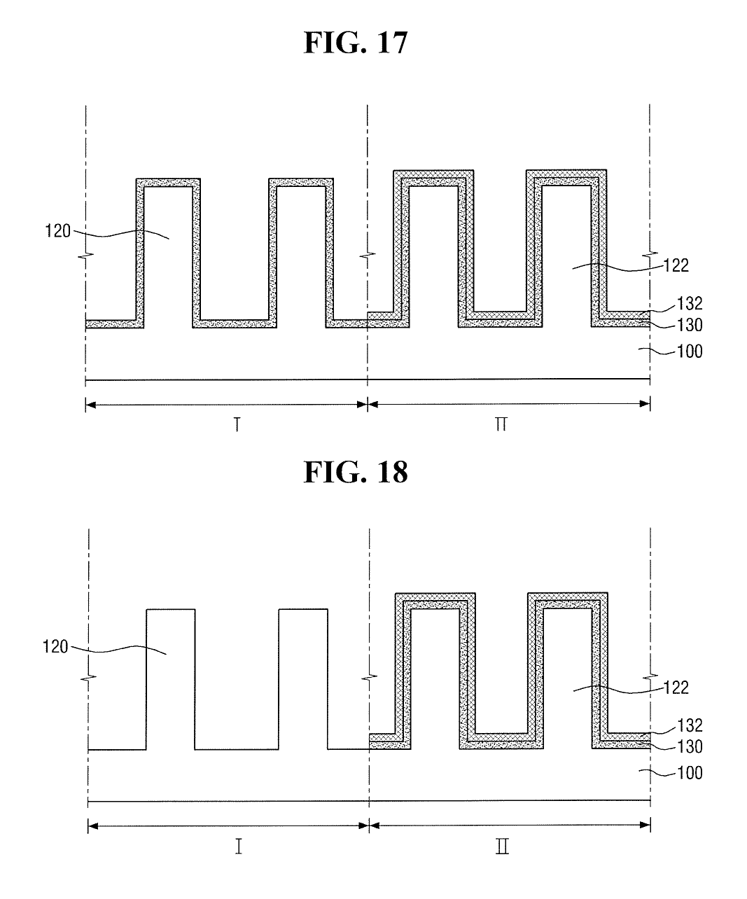

Referring to FIGS. 16 and 17, the first liner pattern 132 is removed from the first region I. In example embodiments of the present inventive concept, the step of removing the first liner pattern 132 from the first region I may include forming a mask pattern 140 in the second region II, and etching the first liner pattern 132 of the first region I using the mask pattern 140.

Then, referring to FIGS. 17 and 18, after the first liner pattern 132 is removed from the first region I, the second liner pattern 130 is removed from the first region I. In example embodiments of the present inventive concept, the step of removing the second liner pattern 130 from the first region I may include etching the second liner pattern 130 in the first region I using the mask pattern 140 in the second region II. After the second liner pattern 130 in the first region I is etched using the mask pattern 140, the mask pattern 140 may also be removed.

In example embodiments of the present inventive concept, the first liner pattern 132 and the second liner pattern 130 in the first region I may be removed using a dry etching or a wet etching including a reactive ion etching (RIE) process.

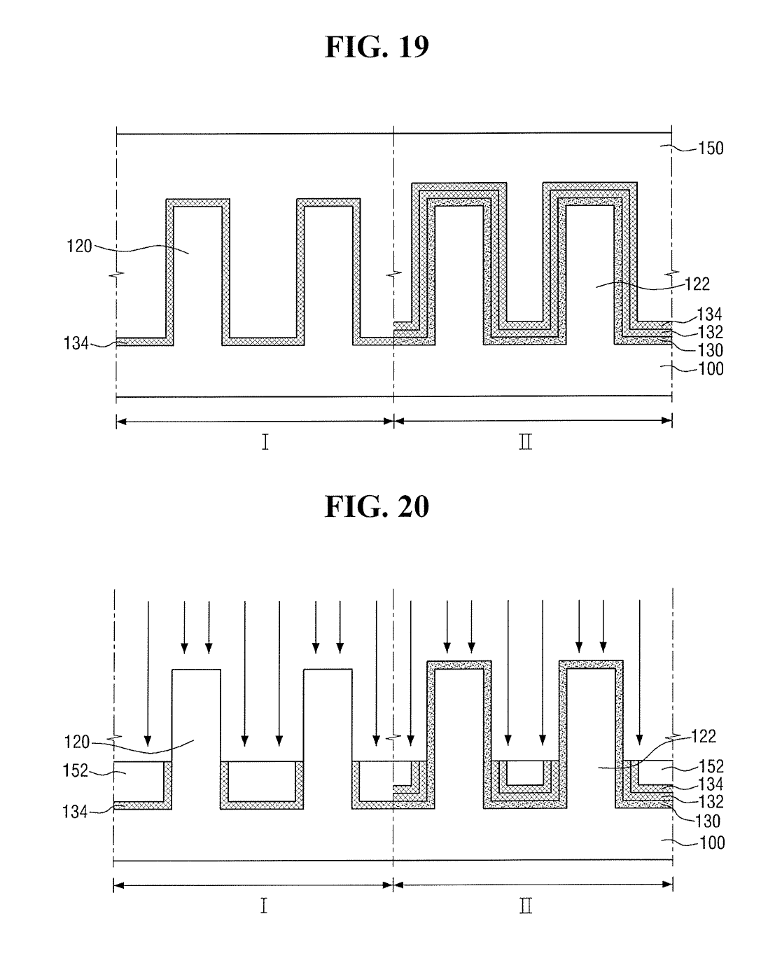

Referring to FIG. 19, a third liner pattern 134 is formed on substrate 100 and first active pattern 120 in the first region I and on the first liner pattern 132, the second liner pattern 130 and the second active pattern 122 in the second region II. In example embodiments of the present inventive concept, the third liner pattern 134 may have a negative polarity. On the other hand, in example embodiments of the present inventive concept, the third liner pattern 134 may include Al₂O₃, HfO₂, or TaO.

As a result, the third liner pattern 134 is formed in the first region I, and the first liner pattern 132, the second liner pattern 130, and the third liner pattern 134 are formed in the second region II. Thereafter, an isolation pattern 150 is formed on the first liner pattern 132, the second liner pattern 130, and the third liner pattern 134 in the first region I and the second region II.

Referring to FIG. 20, the first active pattern 120 is exposed by recessing the isolation pattern 150 to form the isolation pattern 152. The step of exposing the first active pattern 120 by recessing the isolation pattern 150 may include removing a part of the third liner pattern 134 that is formed in the first region I by recessing the isolation pattern 150, and exposing parts of an upper surface and a side surface of the first active pattern 120.

On the other hand, in this embodiment, the third liner pattern 134 and the first liner pattern 132 that are formed in the second region II may be removed when the third liner pattern 134 that is formed in the first region I is removed by recessing the isolation pattern 150. FIG. 20 illustrates that part of the third liner pattern 134 and the first liner pattern 132 remain in the second region II after the isolation pattern 150 is recessed. However, in example embodiments of the present inventive concept, the third liner pattern 134 and the first liner pattern 132 in the second region II may be entirely removed after the isolation pattern 150 is recessed.

In the above-described manner, the third liner pattern 134 may be formed along the upper surface of the substrate 100 and the part of the side surface of the first active pattern 120 in the first region I.

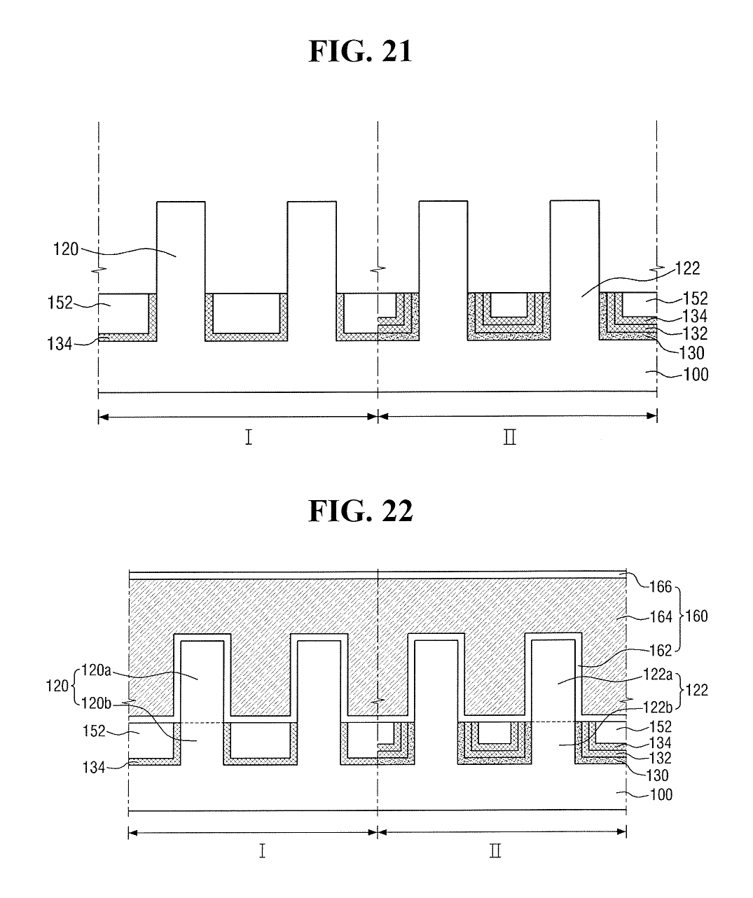

Referring to FIG. 21, after parts of the third liner pattern 134 formed in the first region I and the third liner pattern 134 and the first liner pattern 132 formed in the second region II are removed through recessing the isolation pattern 150, a part of the second liner pattern 130 that is formed in the second region II is removed. Accordingly, parts of the upper surface and the side surface of the second active pattern 122 are exposed. For example, a part of the second liner pattern 130 covering a protruding part of the second active pattern 122 is removed to expose the parts of the upper surface and the side surface of the second active pattern 122.

In the above-described manner, the second liner pattern 130 may be formed along the upper surface of the substrate 100 and the part of the side surface of the second active pattern 122 in the second region II.

Referring to FIG. 22, a dummy gate structure 160 that includes a dummy gate insulating layer 162 and a dummy gate electrode 164 may be formed on the exposed first and second active patterns 120 and 122. In a subsequent process, the dummy gate structure 160 may be replaced by a gate structure that includes a gate insulating layer and a gate electrode. A mask pattern 166 may be used to form the dummy gate structure 160.

In this embodiment, the third liner pattern 134 may be formed on a side surface of the lower region 120b of the first active pattern 120 in the first region I, and the third liner pattern 134 may not be formed on a side surface of the upper region 120a of the first active pattern 120 in the first region I. Further, the second liner pattern 130, the first liner pattern 132, and the third liner pattern 134 may be formed on a side surface of the lower region 122b of the second active pattern 122 in the second region II, and the second liner pattern 130, the first liner pattern 132, and the third liner pattern 134 may not be formed on a side surface of the upper region 122a of the second active pattern 122 in the second region II.

On the other hand, in example embodiments of the present inventive concept, if the third liner pattern 134 and the first liner pattern 132 in the second region II are entirely removed after the isolation pattern 150 is recessed, the second liner pattern 130 may be formed on the side surface of the lower region 122b of the second active pattern 122, and the second liner pattern 130 may not be formed on the side surface of the upper region 122a of the second active pattern 122.

In this embodiment, the polarity of the upper region 120a of the first active pattern 120 may be different from the polarity of the second liner pattern 130. The polarity of the upper region 122a of the second active pattern 122 may be different from the polarity of the third liner pattern 134, and may be equal to the polarity of the second liner pattern 132. On the other hand, the polarity of the upper region 120a of the first active pattern 120 may be different from the polarity of the upper region 122a of the second active pattern 122.

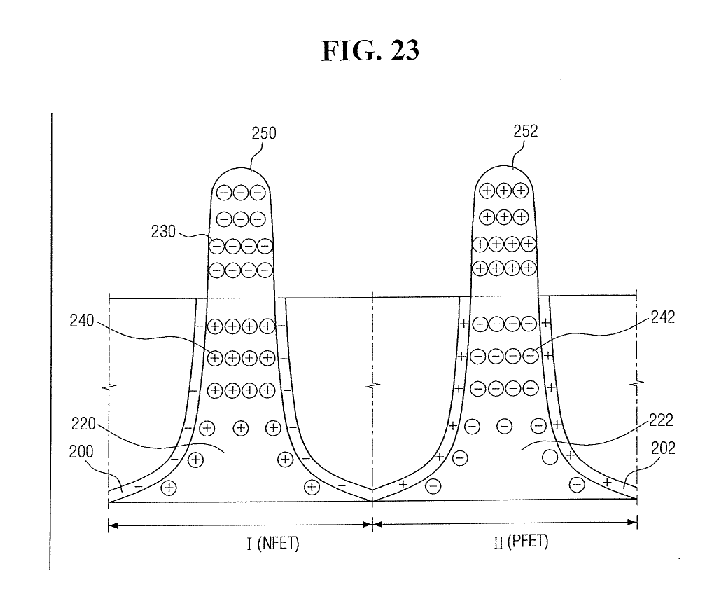

FIG. 23 is a view of a semiconductor device according to example embodiments of the present inventive concept.

In the semiconductor device 1, 2, or 3 according to example embodiments of the present inventive concept, in the case where a first region I is an NMOS region and a second region II is a PMOS region, the polarity of an upper region 250 of a first active pattern 220 may be a negative polarity, and the polarity of a second liner pattern 202 may be a positive polarity. Further, the polarity of an upper region 252 of a second active pattern 222 may be a positive polarity, and the polarity of a first liner pattern 200 may be a negative polarity. In this case, the polarity of a lower region 240 of the first active pattern 220 may become a positive polarity, and the polarity of a lower region 242 of the second active pattern 222 may become a negative polarity. Through such a structure, charge mobility can be increased by suppressing a punch-through phenomenon so that ion injection is not needed or is kept to a minimum. Further, by forming the fin with a narrow width in the semiconductor device 1, 2, or 3 according to example embodiments of the present inventive concept, high density and high performance devices can be realized.

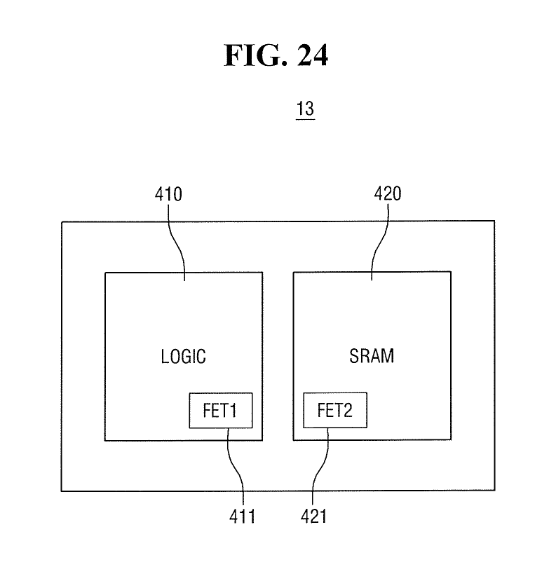

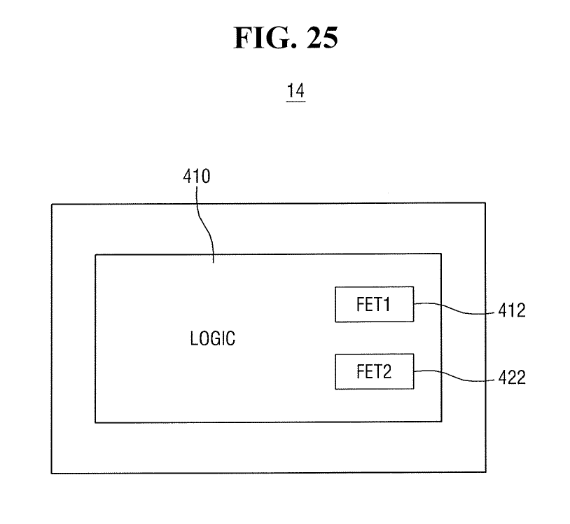

FIGS. 24 and 25 are diagrams of a semiconductor device that is manufactured by a method for manufacturing a semiconductor device according to an example embodiment of the present inventive concept. Hereinafter, an explanation will be made regarding differences between this embodiment and the above-described embodiments.

First, referring to FIG. 24, a semiconductor device 13 that is manufactured by a method for manufacturing a semiconductor device according to an example embodiment of the present inventive concept may include a logic region 410 and a static random access memory (SRAM) formation region 420. An eleventh transistor 411 may be arranged on the logic region 410, and a twelfth transistor 421 may be arranged on the SRAM formation region 420. The eleventh and twelfth transistors 411 and 421 may be finFETs.

Next, referring to FIG. 25, a semiconductor device 14 that is manufactured by a method for manufacturing a semiconductor device according to an example embodiment of the present inventive concept may include a logic region 410, and thirteenth and fourteenth transistors 412 and 422, which are different from each other. The thirteenth and fourteenth transistors 412 and 422 may be arranged in the logic region 410. The thirteenth and fourteenth transistors 412 and 422 may be finFETs. On the other hand, the thirteenth and fourteenth transistors 412 and 422, which are different from each other, may also be arranged in an SRAM region of the semiconductor device 14. FIGS. 24 and 25 illustrate and describe the logic region 410 and the SRAM forming region 420, but the present inventive concept is not limited thereto. For example, the present inventive concept can be applied other regions where memories (e.g., dynamic random access memory (DRAM), magnetoresistive random access memory (MRAM), resistive random access memory (RRAM), and phase change random access memory (PRAM)) are formed.

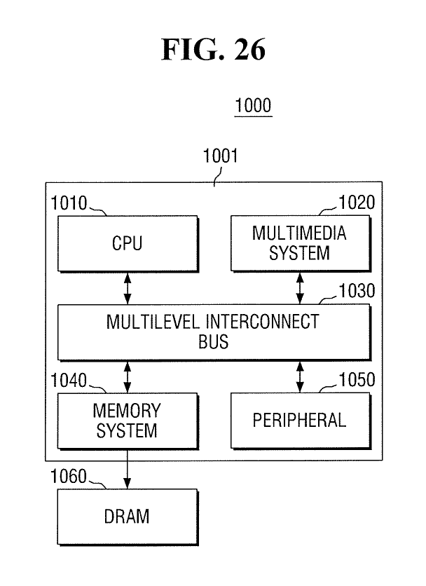

FIG. 26 is a block diagram of a system on chip (SoC) system that includes a semiconductor device according to example embodiments of the present inventive concept.

Referring to FIG. 26, a SoC system 1000 includes an application processor 1001 and a DRAM 1060.

The application processor 1001 may include a central processing unit 1010, a multimedia system 1020, a bus 1030, a memory system 1040, and a peripheral circuit 1050.

The central processing unit 1010 may perform operations to drive the SoC system 1000. In example embodiments of the present inventive concept, the central processing unit 1010 may be configured in a multi-core environment including a plurality of cores.

The multimedia system 1020 may be used when the SoC system 100 performs various kinds of multimedia functions. The multimedia system 1020 may include a three-dimensional (3D) engine module, a video codec, a display system, a camera system, and a post-processor.

The bus 1030 may be used when the central processing unit 1010, the multimedia system 1020, the memory system 1040, and the peripheral circuit 1050 perform data communication with each other. In example embodiments of the present inventive concept, examples of the bus 1030 may include a multilayer Advanced High-performance Bus (AHB) and a multilayer Advanced eXtensible Interface (AXI), but the present inventive concept is not limited thereto.

The memory system 1040 may provide an environment that is used when the application processor 1001 is connected to an external memory (e.g., the DRAM 1060) to perform a high-speed operation. In example embodiments of the present inventive concept, the memory system 1040 may include a separate controller (e.g., a DRAM controller) for controlling the external memory (e.g., the DRAM 1060).

The peripheral circuit 1050 may provide an environment that is used when the SoC system 1000 is connected to the external device (e.g., a main board). Accordingly, the peripheral circuit 1050 may be provided with various interfaces for making the external device compatible with the SoC system 1000 to which it is connected.

The DRAM 1060 may function as an operating memory that is used when the application processor 1001 operates. In example embodiments of the present inventive concept, the DRAM 1060 may be arranged on an outside of the application processor 1001 as illustrated in FIG. 26. For example, the DRAM 1060 and the application processor 1001 may be packaged in the form of a Package on Package (PoP).

At least one of the elements of the SoC system 1000 may include any one of the semiconductor devices according to the example embodiments of the present inventive concept.

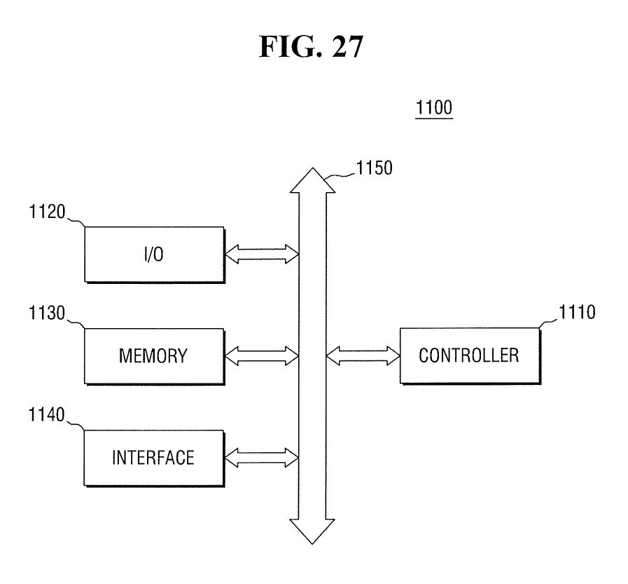

FIG. 27 is a block diagram of an electronic system that includes a semiconductor device according to example embodiments of the present inventive concept.

Referring to FIG. 27, an electronic system 1100 according to an example embodiment of the present inventive concept may include a controller 1110, an input/output (I/O) device 1120, a memory 1130, an interface 1140, and a bus 1150. The controller 1110, the I/O device 1120, the memory 1130, and/or the interface 1140 may be coupled to one another through the bus 1150. The bus 1150 corresponds to a path or paths through which data is transferred.

The controller 1110 may include a microprocessor, a digital signal processor, a microcontroller, or logic elements that can perform functions similar to the microprocessor, the digital signal processor or the microcontroller. The I/O device 1120 may include a keypad, a keyboard, and a display device. The memory 1130 may store data and/or commands. The interface 1140 may transfer the data to a communication network or receive the data from the communication network. The interface 1140 may be of a wired or wireless type. For example, the interface 1140 may include an antenna or a wired/wireless transceiver.

The electronic system 1100 may further include a high-speed DRAM and/or SRAM as an operating memory for the operation of the controller 1110. In this case, as the operating memory, any one of the semiconductor devices 1 to 3 according to the example embodiments of the present inventive concept may be used. Further, any one of the semiconductor devices 1 to 3 according to the example embodiments of the present inventive concept may be provided in the memory 1130, or may be provided as a part of the controller 1110 or the I/O device 1120.

The electronic system 1100 may be applied to a Personal Digital Assistant (PDA), a portable computer, a web tablet, a wireless phone, a mobile phone, a digital music player, a memory card, or all electronic devices that can transmit and/or receive information in wireless environments.

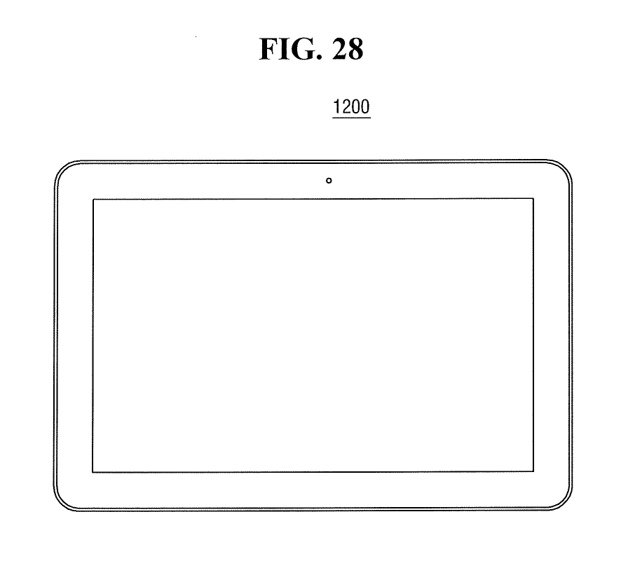

FIGS. 28 to 30 are views of semiconductor systems to which the semiconductor device according to example embodiments of the present inventive concept can be applied.

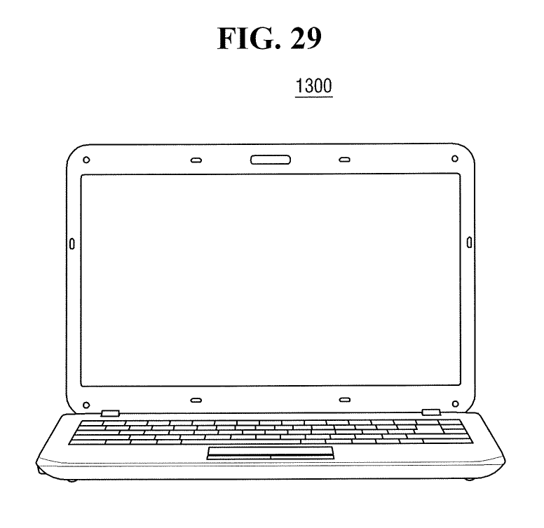

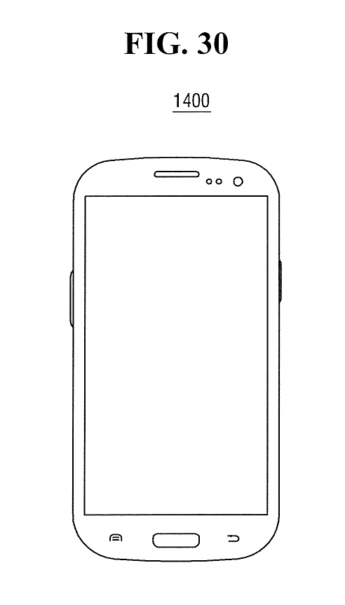

FIG. 28 illustrates a tablet PC 1200, FIG. 29 illustrates a notebook computer 1300, and FIG. 30 illustrates a smart phone 1400. At least one of the semiconductor devices 1 to 3 according to the example embodiments of the present inventive concept may be used in the tablet PC 1200, the notebook computer 1300, or the smart phone 1400.

Further, it is to be understood that the semiconductor device according to example embodiments of the present inventive concept can be applied to other integrated circuit devices. In other words, although the tablet PC 1200, the notebook computer 1300, and the smart phone 1400 have been illustrated as examples of the semiconductor system to which the semiconductor device according to an example embodiment of the present invention can be applied, the present inventive concept is limited thereto. In example embodiments of the present inventive concept, the semiconductor system may be implemented as a computer, an Ultra Mobile PC (UMPC), a workstation, a net-book, a PDA, a portable computer, a wireless phone, a mobile phone, an e-book, a Portable Multimedia Player (PMP), a portable game machine, a navigation device, a black box, a digital camera, a 3D television set, a digital audio recorder, a digital audio player, a digital picture recorder, a digital picture player, a digital video recorder, or a digital video player.

A method of manufacturing a semiconductor device according to an example embodiment of the present inventive concept can suppress a punch through phenomenon of a bulk finFET such that ion injection is not performed or minimized.

While the present inventive concept has been particularly shown and described with reference to example embodiments thereof, it will be understood by those of ordinary skill in the art that various changes in form and details may be made therein without departing from the spirit and scope of the present inventive concept as defined by the following claims.

1. A method for manufacturing a semiconductor device, comprising:
forming a first active pattern in a first region of a substrate and a second active pattern in a second region of the substrate, wherein the first and second active patterns project from the substrate;
forming a second liner pattern on the substrate and the second active pattern in the second region, wherein the second liner pattern has a second polarity;
forming a first liner pattern on the substrate and the first active pattern in the first region, wherein the first liner pattern has a first polarity different from the second polarity;
forming the first liner pattern on the second liner pattern and the second active pattern in the second region;
forming an isolation pattern on the first liner pattern in the first region and the second liner pattern in the second region; and
exposing an upper portion of the first active pattern and an upper portion of the second active pattern by recessing the isolation pattern,
wherein the isolation pattern in the second region covers a lower portion of the second active pattern, the first and second liner patterns are disposed between the isolation pattern and a sidewall of the second active pattern, and the first and second liner pattern are disposed between a bottom of the isolation pattern and the substrate.

2. The method of claim 1, wherein the second polarity is a positive polarity.

3. The method of claim 2, wherein the second liner pattern includes SiN.

4. The method of claim 1, wherein the first polarity is a negative polarity.

5. The method of claim 4, wherein the first liner pattern includes Al₂O₃, HfO₂, or TaO.

6. The method of claim 1, wherein the forming of the second liner pattern on the substrate and the second active pattern in the second region comprises:
forming the second liner pattern on the substrate in the first and second regions, on the first active pattern in the first region, and on the second active pattern in the second region; and
removing the second liner pattern from the first region.

7. The method of claim 6, wherein the removing of the second liner pattern from the first region comprises:
forming a mask pattern in the second region; and
etching the second liner pattern in the first region using the mask pattern.

8. (canceled)

9. The method of claim 1, wherein parts of side surfaces of the first active pattern and the second active pattern are exposed by recessing the isolation pattern.

10. The method of claim 1, wherein the first active pattern and the second active pattern are exposed by removing parts of the first liner pattern formed in the first region and parts of the first liner pattern formed in the second region while recessing the isolation pattern.

11. The method of claim 10, wherein the first active pattern and the second active pattern are exposed by removing a part of the second liner pattern formed in the second region after removing the part of the first liner pattern formed in the first region and the part of the first liner pattern formed in the second region while recessing the isolation pattern.

12-20. (canceled)
